(19) United States
(12) Patent Application Publication
(10) Pub. No.: US 2026/0308395 A1
(43) Pub. Date: Oct. 8, 2026

(54) ONE-STEP METHOD FOR MANUFACTURING AN INK COMPRISING AN N-TYPE CONDUCTING POLYMER

(71) Applicant: WESTRA MATERIALS AB, Norrköping (SE)

(72) Inventors: Simone FABIANO, Norrköping (SE); Chi-Yuan YANG, Norrköping (SE); Marc-Antoine STOECKEL, Norrköping (SE); Jun-Da HUANG, Norrköping (SE); Qifan LI, Norrköping (SE)

(73) Assignee: WESTRA MATERIALS AB, Norrköping (SE)

(21) Appl. No.: 19/483,394

(22) PCT Filed: May 17, 2023
(86) PCT No.: PCT/EP2023/063322

§ 371 Date: Nov. 11, 2025

(51) Int. Cl. C09D 5/24; C08G 61/12; C09D 165/00

(52) U.S. Cl. CPC C09D 5/24; C08G 61/125; C09D 165/00; C08G 2261/11; C08G 2261/3242; C08G 2261/43

(57) ABSTRACT

The present invention relates to a method for manufacturing an ink comprising n-type conducting polymer, the method comprising the steps of: a) adding a monomer to a solvent system comprising a polar aprotic solvent and an oxidizing agent in the presence of a catalyst, thus providing a reaction solution; b) allowing the monomer to polymerize in the reaction solution thus obtaining an ink comprising n-type conducting polymer, wherein the catalyst is a quinone or a quinone precursor, and wherein the catalyst comprises at least one branched side chain.

### TECHNICAL FIELD

The present invention relates to a method for manufacturing an ink comprising an n-type conducting polymer, and an ink comprising the n-type conducting polymer obtained by such a method.

### BACKGROUND OF THE INVENTION

Conducting polymer inks have broad industrial applications, such as antistatic coatings, polymer capacitors, organic solar cells, displays (LCD/OLED), and printed electronics. To date, PEDOT:PSS has been state-of-the-art commercialized p-type (hole-transporting) conducting polymer ink. PEDOT:PSS demonstrates high electrical conductivity over 1 S cm⁻¹ in simple casting methods, and electrical conductivity over 4000 S cm⁻¹ after secondary-doping or post-treating. However, n-type (electron-transporting) conducting polymers are crucial when considering complementary components in semiconducting devices and circuitry. Recently, Fei Huang et al. reported a method for manufacturing a solution-processed n-type conducting polymer poly(benzodifurandione) (PBFDO) with electrical conductivity over 2000 S cm⁻¹ (Nature, 2022, s41586-022-05295-8). In order for the polymerization reaction to occur, duroquinone (TMQ) as a catalyst needs to be added. TMQ is not environmentally friendly and non-renewable. Further, TMQ has high crystallinity and is readily crystallizable, and will thus affect the film formation during printing. Therefore, PBFDO ink needs to undergo dialysis in order to remove TMQ, followed by solvent removal since the dialysis step inevitably leads to dilution of the ink.

Therefore, there is a need for developing an improved method for manufacturing an ink comprising n-type conducting polymers, in particular involving renewable and environmentally friendly catalysts.

### SUMMARY OF THE INVENTION

Considering the above, the present invention aims to solve the problems of the prior art. To this end, the present invention relates to a method for manufacturing an ink comprising n-type conducting polymer, the method comprising the steps of:
a) adding a monomer to a solvent system comprising a polar aprotic solvent and an oxidizing agent in the presence of a catalyst, thus providing a reaction solution;
b) allowing the monomer to polymerize in the reaction solution thus obtaining an ink comprising n-type conducting polymer.

The catalyst is a quinone or a quinone precursor, and comprises at least one branched side chain. By the term “quinone precursor” is understood a species that is able to form a quinone structure. The side chain may comprise from 3 to 100 carbon atoms. The side chain may further comprise at least one functional group, e.g. a hydroxyl group. Further, the side chain may further comprise a branch centre. Further, the side chain may comprise at least one chiral centre. It has been shown that the catalyst according to the present invention does not crystallize during the polymerisation reaction, since the at least one branched side chain prevents such a crystallization. Since the catalyst does not crystallize, the dialysis step is eliminated.

Thus, one of the advantages of the method of the present invention is that dialysis step in order to remove the catalyst is eliminated, since the catalyst according to the present invention does not crystallize due to the presence of at least one branched side chain.

The monomer has the central symmetrical benzene ring as the skeleton, active hydrogen and at least one electron-withdrawing group at the benzylic position. The electron-withdrawing groups may be carbonyl, carboxyl, amide, alkoxy acyl or the like

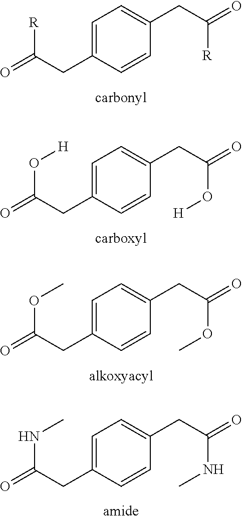

Further, the monomer may be in the form of a heterocyclic moiety having a central symmetrical benzene ring fused with at least one, preferably at least two rings, preferably five-membered rings. The monomer further comprises an active hydrogen and at least one electron-withdrawing group at the benzylic position. In particular, the monomer may be 3,7-dihydrobenzo[1,2-b:4,5-b′]difuran-2,6-dione (HBFDO), 5,7-dihydropyrrolo[2,3-f]indole-2,6 (1H,3H)-dione, or 3,7-dihydrobenzo[1,2-b:4,5-b′]dithiophene-2,6-dione.

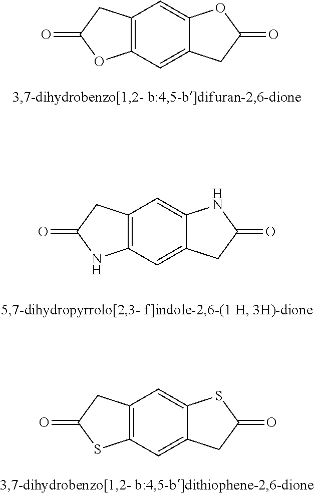 [SMILES: O=C1Cc2cc3c(cc2O1)CC(=O)O3 ; O=C1Cc2cc3c(cc2N1)CC(=O)N3 ; O=C1Cc2cc3c(cc2S1)CC(=O)S3]

In particular, the monomer is 3,7-dihydrobenzo[1,2-b:4,5-b′]difuran-2,6-dione (HBFDO). In such an embodiment, the n-type conducting polymer is poly(benzodifurandione) (PBFDO).

According to a particular embodiment, the catalyst may be Vitamin E. As commonly known in the art, Vitamin E is a group of eight fat soluble compounds that include four tocopherols and four tocotrienols, as illustrated below:

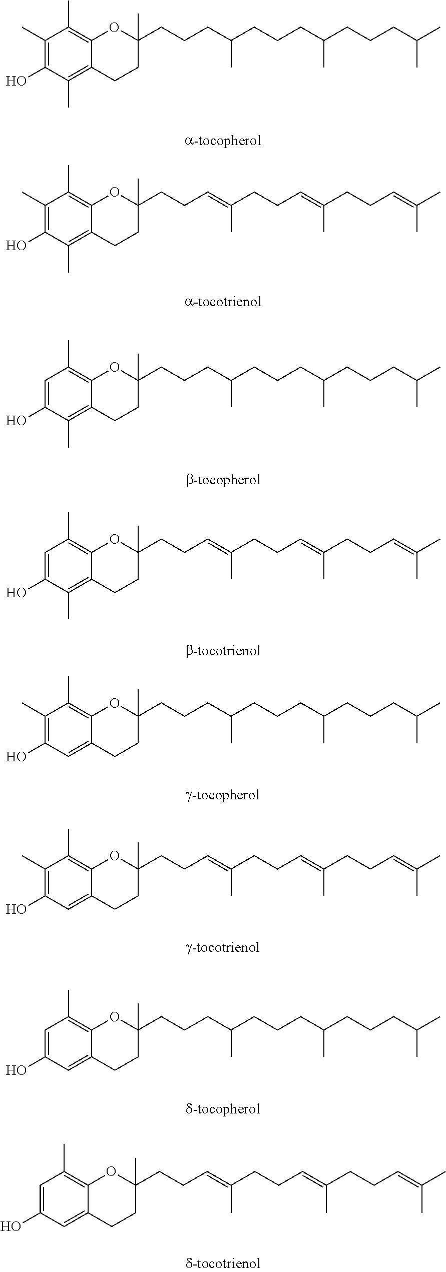

It should be noted that according to the present invention, the term Vitamin E implies at least one of the species above. In other words, each of the species above may be present in its pure form in the reaction solution, or at least two of the species above may be present in any combination. Consequently, vitamin E may be selected from a group consisting of: α-tocopherol, β-tocopherol, γ-tocopherol, δ-tocopherol, α-tocotrienol, β-tocotrienol, γ-tocotrienol, δ-tocotrienol and mixtures thereof.

Vitamin E (generic term for tocopherols and tocotrienols) is a natural product with high redox activity. Vitamin E can be synthesized in plants that undergo photosynthesis, and it can be extracted in large quantities from plants. All vitamin E molecules have branched long hydrocarbon side chains, and they are natural oily substances with no crystallinity at room temperature. According to the method of the present invention, vitamin E may be used as catalyst to synthesize ink comprising n-type conducting polymer in one step or in one-pot without the need for post treatment, such as dialysis and solvent removal. Compared with the three-step method reported by Fei Huang, the method of the present invention achieves a great simplification.

It has been surprisingly shown that vitamin E itself has no catalytic effect, but the oxidized form of vitamin E does. In the presence of an oxidizing agent, vitamin E forms a benzoquinone derivative. According to the present invention, in-situ oxidation initiates the polymerisation reaction. The method of the present invention thus offers the advantage of a simplified and cost-efficient method for manufacturing an ink comprising n-type conducting polymer compared to the methods known in the art. A great advantage of using Vitamin E as catalyst is its availability, low price and non-toxicity.

In a particular embodiment, the polar aprotic solvent is DMSO, and the oxidizing agent is hydrogen bromide (HBr). The HBr is volatile and does not affect film formation when the ink is printed.

Alternatively, the oxidizing agent is an ionic liquid comprising a cation and an anion. In such an embodiment, the method further comprises a step of:
a′) electrolysing the reaction solution,
wherein the step a′) occurs simultaneously with or after step a.

In particular, the step a′) may occur using a nickel cathode and a carbon anode under voltage in the range from 4 to 6 V for a period in the range from 10 to 60 min.

The cation in the ionic liquid may be selected from a group consisting of 1-ethyl-3-methylimidazolium (EMIM), 1-butyl-3-methylimidazolium (BMIM), 1-allyl-3-methylimidazolium (AMIM), 1-hexyl-3-methylimidazolium (HMIM), butyl-methyl pyrrolidinium (BMP), propyl-methyl pyrrolidinium (PMP), triethyl sulfonium and mixtures thereof. The structures of the cations are shown below.

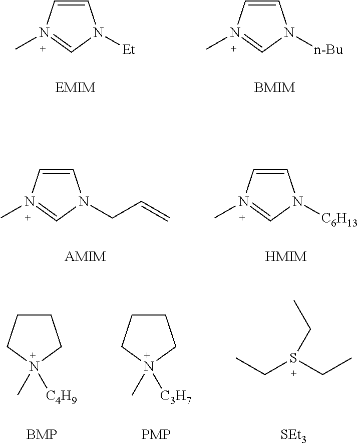

According to the present invention, the anion may be selected from a group consisting of chloride (Cl⁻), bromide (Br⁻), iodide (I⁻), acetate (OAc), tetrafluoro borate (BF₄⁻), hexafluoro phosphate (PF₆⁻), bis-trifluoromethanesulfonimide (TFSI), trifluoromethanesulfonate (OTf), dicyanamide (DCA), hydrogen sulphate (HSO₄⁻), ethyl sulphate (ESO₄⁻), thiocyanate (SCN), tosylate (OTs), mesylate (OMs), tetrachloro aluminate (AlCl₄⁻), diethyl phosphate (DEP), dimethyl phosphate (DMP), lactate (La), L-alanine anion (APP) and mixtures thereof. The structures of the anions are illustrated below.

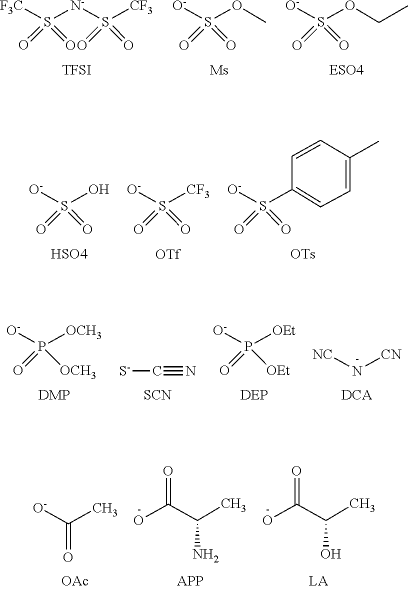

As mentioned above, the solvent system according to the method of the present invention comprises a polar aprotic solvent. The polar aprotic solvent may be dimethyl sulfoxide (DMSO), dimethyl formamide (DMF), dimethyl acetamide (DMA) or a combination thereof.

The ratio between the oxidizing agent and the vitamin E may be in the range from 0.1 to 100, preferably from 0.25 to 5, more preferably from 1 to 3.

The polymerisation reaction, i.e. step b) of the method of the present invention, may occur at a temperature from 20° C. to 150° C.

In order to improve cost efficiency of the method according to the present invention even further, the method according to the present invention may further comprise a step of:
c) removing the catalyst by extraction and recycling the catalyst.

The extraction may be performed using alkanes or ethers.

The general overview of the method of the present invention may be summarized as follows:

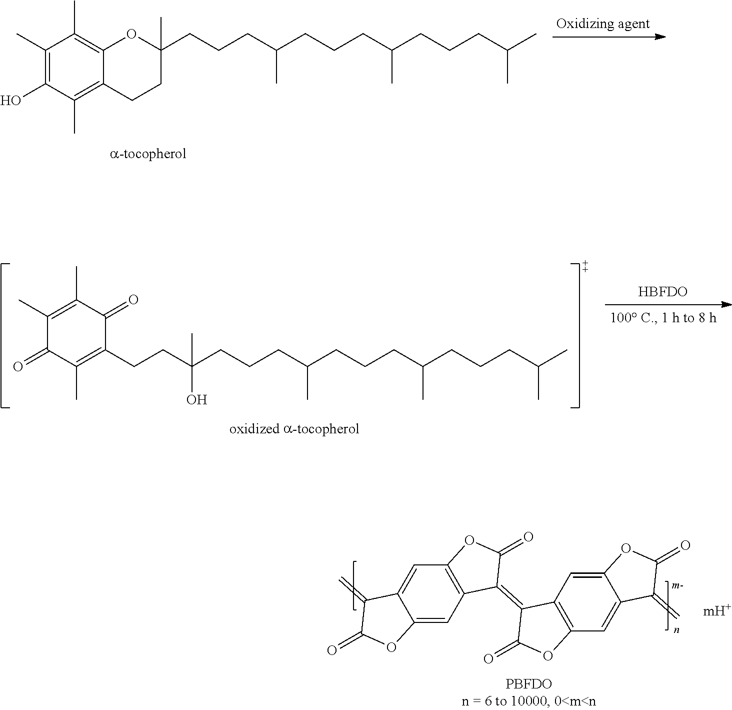

The present invention further relates to an ink comprising an n-type conducting polymer, wherein the ink is manufactured by the method as described above.

The n-type conducting ink of the present invention may thus be spin-coated or drop-cast in air and ambient temperature, forming the film having thicknesses from 1 nm to 1 cm, more preferably from 10 nm to 1 μm. Such a film may exhibit electrical conductivity in the order of 1000 S/cm.

As mentioned above, the n-type conducting ink according to the present invention, may be used in an organic optical or electronic device, such as OECTs, thermoelectric devices, ternary logic inverters, OPVs, OLEDs, organic supercapacitors, batteries, fuel cells, sensors and memories.

### BRIEF DESCRIPTION OF THE DRAWINGS

Embodiments of the invention will now be described by way of example with reference to the accompanying drawings, of which:

FIG. 1 shows the steps of the method according to the first embodiment of the present invention;

FIG. 2 shows the steps of the method according to the second embodiment of the present invention;

FIG. 3a depicts electrical conductivity of PBFDO ink catalysed by different equivalents of vitamin E without dialysis process;

FIG. 3b illustrates comparison of electrical conductivity of the PBFDO ink catalysed using TMQ and vitamin E, respectively;

FIGS. 4a-4d illustrate comparison of GIWAXS data of the PBFDO ink catalysed using TMQ and Vitamin E with/without dialysis process, respectively.

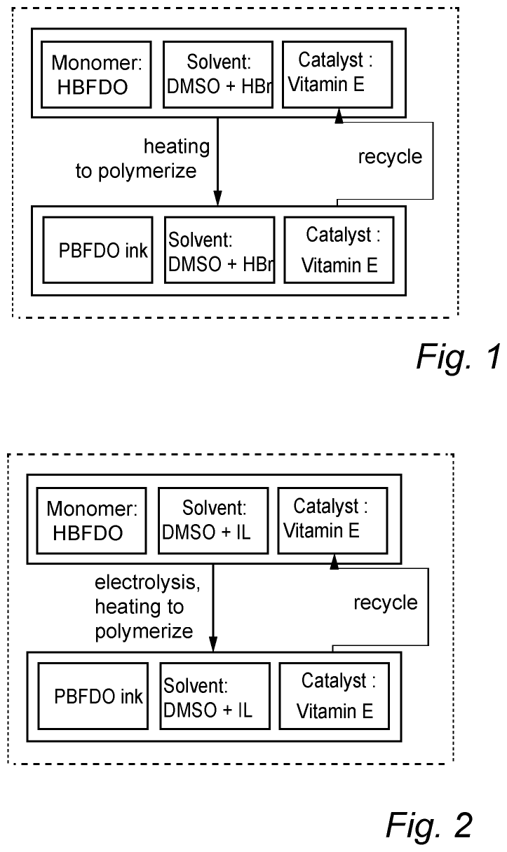

### DETAILED DESCRIPTION OF THE INVENTION

As mentioned above, the present invention relates to a method for manufacturing an ink comprising n-type conducting polymer, the method comprising the steps of:
a) adding a monomer to a solvent system comprising a polar aprotic solvent and an oxidizing agent in the presence of vitamin E, thus providing a reaction solution;
b) allowing the monomer to polymerize in the reaction solution thus obtaining an ink comprising n-type conducting polymer,
   wherein the catalyst is a quinone or a quinone precursor, and wherein the catalyst comprises at least one branched side chain.

High electrical conductivity PBFDO ink was synthesized, catalysed by Vitamin E. Vitamin E can be easily in-situ converted to its oxidized intermediate by adding 2 equivalents (relative vitamin E) of concentrated HBr (commercially available 48% aqueous solution) to its DMSO solution.

Vitamin E can also be easily in-situ converted to its oxidized intermediate by electrolysis in its DMSO solution with 2 equivalents (relative vitamin E) of ionic liquid electrolyte, nickel cathode, carbon anode, and electrolysis voltage of 4-6 V for 10-60 min.

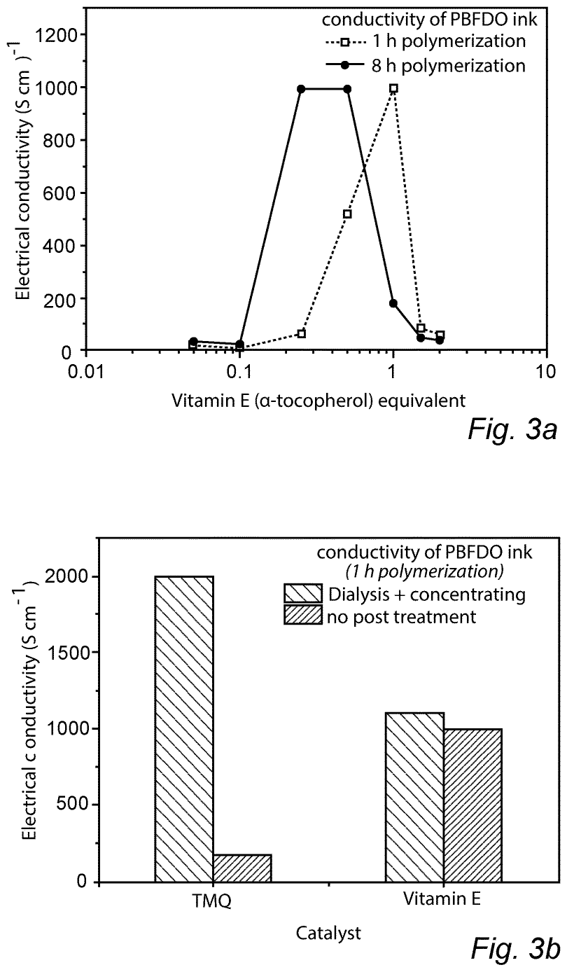

After the catalyst comprising vitamin E according to the above has been obtained, HBFDO (5-15 mg/mL) was added to the DMSO solutions of oxidized vitamin E and heated to 100° C. to polymerize. After cooling to room temperature, the PBFDO ink was obtained without further post treatment. A high electrical conductivity of 1000 S/cm is achieved, as depicted in FIG. 3a.

It was further confirmed that vitamin E, HBr, or ionic liquid do not need to be removed from the ink, and they have little impact on the film formation and conductivity of the ink (FIG. 3b). It was verified that TMQ must be removed from the ink as it greatly affects the ink's film formation and conductivity (FIG. 3b).

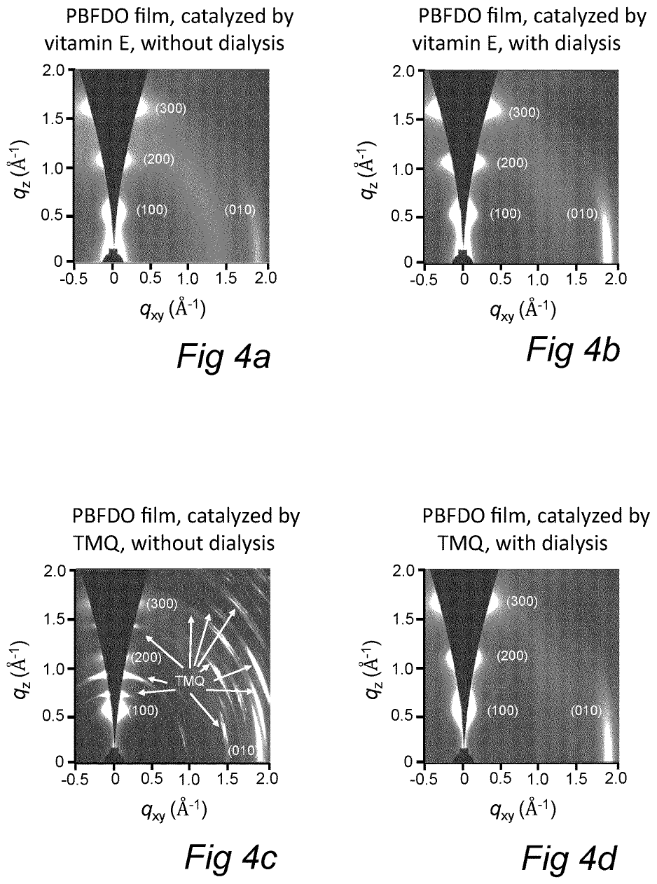

It was demonstrated that Vitamin E does not affect the final microstructure of coated PBFDO films, regardless of whether the dialysis process was used or not (FIGS. 4a, 4b). On the other hand, it was confirmed that TMQ must be removed by dialysis from the ink to prevent formation of TMQ crystals that affect the final film microstructure and conductivity (FIGS. 4c, 4d). Hence, the method of the present invention eliminates the need for the dialysis step, improving efficiency and reducing time consumption.

In summary, a one-pot method for the synthesis of highly conductive n-type polymer inks using vitamin E as a catalyst has been developed. The method does not require post-processing. The achieved conductivity was measured to be as high as 1000 S/cm.

Although the present invention has been described with reference to various embodiments, those skilled in the art will recognize that changes may be made without departing from the scope of the invention. It is intended that the detailed description be regarded as illustrative and that the appended claims including all the equivalents are intended to define the scope of the invention.

1. A method for manufacturing an ink comprising n-type conducting polymer, said method comprising the steps of:
a) adding a monomer to a solvent system comprising a polar aprotic solvent and an oxidizing agent in the presence of a catalyst, thus providing a reaction solution; and
b) allowing said monomer to polymerize in said reaction solution, thus obtaining an ink comprising an n-type conducting polymer,
wherein said catalyst is a quinone or a quinone precursor, and wherein said catalyst comprises at least one branched side chain.

2. The method according to claim 1, wherein said at least one branched chain comprises at least one chiral centre.

3. The method according to claim 1, wherein said catalyst is vitamin E.

4. The method according to claim 3, wherein said vitamin E is selected from a group consisting of: α-tocopherol, β-tocopherol, γ-tocopherol, δ-tocopherol, α-tocotrienol, β-tocotrienol, γ-tocotrienol, δ-tocotrienol, and mixtures thereof.

5. The method according to claim 1, wherein said polar aprotic solvent is DMSO and said oxidizing agent is hydrogen bromide (HBr).

6. The method according to claim 1, wherein said oxidizing agent is an ionic liquid comprising a cation and an anion, and wherein said method further comprises a step of:
a′) electrolysing said reaction solution,
wherein said step a′) occurs simultaneously with or after step a).

7. The method according to claim 6, wherein said step a′) occurs using a nickel cathode and a carbon anode under voltage in a range from 4 to 6 V for a period in a range from 10 to 60 min.

8. The method according to claim 6, wherein said cation in said ionic liquid is selected from a group consisting of 1-ethyl-3-methylimidazolium (EMIM), 1-butyl-3-methylimidazolium (BMIM), 1-allyl-3-methylimidazolium (AMIM), 1-hexyl-3-methylimidazolium (HMIM), butyl-methyl pyrrolidinium (BMP), propyl-methyl pyrrolidinium (PMP), triethyl sulfonium, and mixtures thereof.

9. The method according to claim 6, wherein said anion is selected from a group consisting of chloride (Cl⁻), bromide (Br⁻), iodide (I⁻), (OAc), borate acetate tetrafluoro (BF₄⁻), hexafluoro phosphate (PF₆⁻), bis-trifluoromethanesulfonimide (TFSI), trifluoromethanesulfonate (OTf), dicyanamide (DCA), hydrogen sulphate (HSO₄⁻), ethyl sulphate (ESO₄⁻), thiocyanate (SCN), tosylate (OTs), mesylate (OMs), tetrachloro aluminate (AlCl₄⁻), diethyl phosphate (DEP), dimethyl phosphate (DMP), lactate (La), L-alanine anion (APP), and mixtures thereof.

10. The method according to claim 1, wherein said polar aprotic solvent is dimethyl sulfoxide (DMSO), dimethyl formamide (DMF), dimethyl acetamide (DMA) or a combination thereof.

11. The method according to claim 1, wherein the ratio between said oxidizing agent and said catalyst is in the range from 0.1 to 100, preferably from 0.25 to 5, more preferably from 1 to 3.

12. The method according to claim 1, wherein said step b) occurs at a temperature from 20° C. to 150° C.

13. The method according to claim 1, wherein said monomer is 3,7-dihydrobenzo[1,2-b:4,5-b]difuran-2,6-dione (HBFDO), and wherein said n-type conducting polymer is poly(benzodifurandione) (PBFDO).

14. The method according to claim 1, wherein said method further comprises a step of:
e) removing said catalyst by extraction and recycling said catalyst.

15. An ink comprising an n-type conducting polymer, said ink manufactured by the method according to claim 1.

16. The method according to claim 11, wherein the ratio between said oxidizing promoter and said catalyst is in the range from 0.25 to 5.

17. The method according to claim 11, wherein the ratio between said oxidizing promoter and said catalyst is in the range from 1 to 3.
